(19) United States
(12) Patent Application Publication
(10) Pub. No.: US 2009/0314340 A1
(43) Pub. Date: Dec. 24, 2009

(54) POLYMER-BASED SOLAR CELL

(75) Inventors: Ulrich Schindler, Furth (DE); Achim Hansen, Zug (CH); Andreas Schilling, Hagendorn (CH)

Correspondence Address: HOFFMANN & BARON, LLP, 6900 JERICHO TURNPIKE, SYOSSET, NY, 11791, US

(73) Assignee: LEONHARD KURZ Stiftung & Co. KG, Furth (DE)

(21) Appl. No.: 12/309,384

(22) PCT Filed: Jul. 18, 2007
(86) PCT No.: PCT/EP2007/006359

§ 371 Date: Feb. 27, 2009

(30) Foreign Application Priority Data
Jul. 20, 2006 (DE) 10 2006 034 095.7
Feb. 22, 2007 (DE) 10 2007 008 610.7

(51) Int. Cl. H01L 31/00; H01L 21/50

(52) U.S. Cl. 136/256; 438/65; 257/E21.499

(57) ABSTRACT

Described are processes for enlarging the surface area of a polymer-based solar cell relative to a flat surface and/or for enlarging the active surface area of the organic semiconductor layer of the solar cell in relation to a flat surface. There is further described a polymer-based solar cell (1) in which the active surface of the organic semiconductor layer (13) has a surface profile which enlarges the surface area in relation to a flat surface profile. The surface has raised portions and/or depressions.

The invention concerns a polymer-based solar cell and a process for the production thereof.

Polymer-based solar cells (for example flexible solar cells) hitherto have levels of efficiency which are in the range of between 3 and 5%. These are levels of efficiency which are markedly lower than those of inorganic solar cells.

If inexpensive production processes such as for example the roll-to-roll process are used for the production of flexible polymer-based solar cells, then mass production of solar cells is conceivable, to a considerable extent.

The object of the present invention is now that of providing a polymer-based solar cell enjoying improved efficiency and processes for the production thereof.

The object of the invention is attained by a process for the production of a solar cell unit comprising a polymer-based solar cell having at least one carrier substrate and at least one organic semiconductor layer having a top side towards a light source and a rear side away from the light source, wherein it is provided that the solar cell after production thereof is so shaped that at least the top side of the solar cell has a surface profile which enlarges the surface area of the top side in relation to a flat surface profile.

The object is further attained by a process for the production of a polymer-based solar cell having at least one carrier substrate and at least one organic semiconductor layer with a top side towards a light source and a rear side remote from the light source, wherein it is provided that a surface relief is shaped into a layer of the solar cell and one or more electrical functional layers including the organic semiconductor layer or layers is applied to the shaped surface relief so that the top side of the organic semiconductor layer has a surface profile which enlarges the surface area of the organic semiconductor layer in relation to a flat surface profile.

The object is further attained by a polymer-based solar cell having at least one carrier substrate and an organic semiconductor layer with a top side towards a light source and a rear side remote from the light source, wherein it is provided that at least the top side of the organic semiconductor layer has a surface profile which enlarges the surface area of the top side in relation to a flat surface profile.

The process according to the invention means that a polymer-based solar cell, referred to hereinafter as a polymer solar cell, can be provided with an enlarged surface area in a very simple and effective fashion so that the efficiency of the resulting solar cell is increased in comparison with a polymer solar cell provided with a flat top side, for example also by virtue of multiple reflections. The proposed processes provide both microscopic and also macroscopic deformations to afford the enlarged surface area, wherein further advantageous configurations are possible by a combination of the processes, as described in greater detail hereinafter.

In that way, with the same mounting area for the polymer solar cell, it is possible to provide an enlarged surface area for the semiconductor layer responsible for converting the radiant energy of the light into electrical energy, whereby the efficiency of the polymer solar cell according to the invention is also increased by virtue of multiple reflections in comparison with a polymer solar cell with a smooth surface.

The organic semiconductor layer is generally a system comprising a plurality of semiconductor layers which interact.

Further advantageous configurations are set forth in the appendant claims.

It can be provided that the solar cell is laminated on to a shrink film and thereafter the solar cell unit is subjected to a temperature treatment. The solar cell can therefore be produced as hitherto for example using a roll-to-roll process in the form of a mass-produced item and can be provided with an enlarged active surface area by a temperature treatment, by the shrink film folding up the solar cell laminated thereonto due to the action of increased temperature, for example in a range of between 80° C. and 250° C. One or more solar cells can be laminated on to the shrink film and form the solar cell unit.

It can however also be provided that a shrink film is used for the carrier substrate of the solar cell and after its manufacture the solar cell is subjected to a temperature treatment. That procedure is admittedly less expensive but has a tighter process window during the roll-to-roll printing operation as it is necessary to ensure that the shrink film does not change its dimensions during the printing and drying procedure. With that embodiment the ‘lamination’ process step is eliminated, whereby the manufacturing costs can be reduced.

It is possible that a unidirectional shrink film is used. With such a shrink film the solar cell can also be of a configuration in the shape of corrugated cardboard.

It is also possible that a bidirectional shrink film is used. The surface of the solar cell can thus be of a knob-form configuration after the shrink operation so that this provides a further enlarged active surface area for the solar cell, in comparison with the aforementioned configuration.

It can be provided that an opaque or transparent or semi-transparent shrink film is used. A transparent shrink film can be advantageous if light is also intended to impinge on the active layer of the solar cell from the rear side thereof or if it is provided that solar cells are stacked in mutually superposed relationship, as set forth hereinafter.

It can further be provided that an electrically non-conducting shrink film is used. Such a non-conducting shrink film can be formed for example with through-contacting means in order to electrically connect a plurality of solar cells together or to pass all connections of the solar cells to a connecting surface.

It can also be provided that an electrically conducting shrink film is used. The shrink film can be of a partially conducting nature. For example the shrink film can have conductor tracks which are suitable for electrically connecting a plurality of solar cells together, that is to say to provide series circuits and/or parallel circuits of solar cells. It is possible in that way to produce solar cell units which deliver a higher output voltage than an individual solar cell.

It is possible that the shrink film is at least region-wise lacquered and/or coated prior to the temperature treatment. Such a lacquering or coating can be provided for example to form electrical conductor tracks on the shrink film or to influence the shrink characteristics of the shrink film in a specifically targeted fashion. For example, the deformation profile in the form of corrugated cardboard, as described hereinbefore, can be produced particularly well by virtue of a non-shrinking coating which is in strip form and which is oriented in parallel relationship, because coated regions can act as desired bend lines, between which the shrink film adopts an upwardly curved configuration. In that case the degree of curvature after the shrink process can be influenced by way of the layer thickness in the lacquered regions.

It can further be provided that light-diffracting and/or light-scattering and/or light-conducting and/or light wavelength-changing particles and/or particle mixtures are added to the lacquer and/or the coating material. The above-mentioned additives mean that at the same time the shrink film can be adapted to deflect the light incident on the solar cell on to the active regions thereof. By virtue of changes in the light wavelength, for producing the solar current it is possible to involve spectral ranges which lie outside the sensitisation of the active layer.

In a further advantageous configuration it is provided that the shrink film is at least region-wise prestructured. It can therefore be provided for example that the shrink film has particularly well deformable regions, at which the shrink film is preferably folded up. This can involve regions of smaller thickness, but it is also possible for example to provide that those regions are weakened in respect of their flexural strength by perforations.

It can further be provided that a multi-layer shrink film is used, the layers of which involve different shrink characteristics. This can involve shrink films which bear against each other over their entire surface area. It is however also possible to provide one or more of the mutually superposed shrink films only in region-wise manner and in that way for example they can act like rubber threads which are introduced into a fabric and which lay the fabric in folds.

In a further advantageous configuration it is provided that the solar cell is shaped by an inmold process. In the inmold process a film to be shaped is pressed under pressure into a mold by means of a medium injected behind the film and is shaped in that way. The injected medium can be for example a heated thermoplastic material such as ABS/PC or PMMA which fixes the shaped film after it sets.

Thus the mold is for example an injection molding mold which on one side has the surface relief, in accordance with which the solar cell is to be shaped. The solar cell is part of an inmold film which is placed in the injection molding mold and then backed by injection with fluid plastic injection molding material from the side of the inmold film, that is opposite to that surface relief. In addition it is also possible for a vacuum to be applied between the injection molding mold half which has the surface relief and the inmold film bearing thereagainst, so that correct shaping of the surface relief in the inmold film is not impeded by air bubbles or the like. The heat and pressure of the injection molding material which is injected into the injection molding mold provide that the inmold film which includes the solar cell is shaped in accordance with the surface profile of the injection molding mold and the shaping is then further fixed and stabilised by the injection molding material cooling. In that case the inmold film is preferably made up of a PET film which is between 15 and 40 μm thick, a release layer and a transfer layer which includes the solar cell. The polyester film is pulled off after cooling of the injection molding material or upon release of the molding from the injection molding mold. In addition it is also possible for the inmold film not to have a release layer and for the polyester film to remain on the molding. The latter procedure however is less usual.

It can further be provided that the solar cell is shaped by a touch forming process. In that case the solar cell is applied to an especially stretchable polyester carrier, the thickness of which is in the region of 100 μm. Then, shaping is effected by means of a mold portion at a temperature in the range of 120° C., using a diaphragm press. What is important in this connection is the individual cycle times which greatly influence the end product and which have to be individually tested out.

A film with a solar cell, that is suitable for such a procedure, comprises for example the following layers:
carrier layer
separation layer
protective lacquer layer
solar cell or cells
adhesive layer.

The separation layer and the protective lacquer layer are preferably of thicknesses in the range of between 1 and 3 μm. The adhesive layer is preferably also of a thickness in the range of between 1 and 3 μm, in which respect the thickness and the composition of the adhesive layer can depend on the substrate.

It can further be provided that the solar cell is shaped by a deep drawing process. For that purpose it can be provided that a film including the solar cell is applied, for example by adhesive, to a deep-drawable substrate such as for example an ABS plate of a thickness of between 0.5 and 1 mm, and then the film with the substrate is shaped in a deep drawing process to constitute the surface relief. The solar cell is applied to the ABS plate which is referred to here by way of example, by way of a rolling process. Thereafter it is gripped in a vacuum machine and deep drawing is effected by way of a partially heated metal mold, by means of vacuum, with the result that the coated ABS plate has assumed the shape of the metal mold.

It is also possible for the substrate to comprise a film of ABS, PVC or Plexiglas. The structure of the film is similar to that already referred to above. Disposed on a carrier are one or more separation layers, a protective lacquer or a protective lacquer packet, the solar cell structure and an adhesive layer. Further layers can be provided if particular end properties are required.

Both in the touch forming process and also in the deep drawing procedure, it is possible to provide for backing of the shaped film by injection therebehind in order to permanently fix the shaping of the film.

The above-described injection medium can be an electrically conductive injection medium if particular applications are required.

It can also be provided that a partially electrically conductive injection medium is used or that an electrically non-conducting injection medium is used.

It can further be provided that an opaque or transparent or semitransparent injection medium is used. It is also provided that the injection medium is modified in a comparable manner to the shrink film described hereinbefore, in which respect in principle any combinations are possible. It is therefore also possible to back shrunk solar cells by an injection process or to connect solar cells together by injection backing thereof. In that respect it can also be provided that metallised contact locations are introduced into the injection backing.

As already stated hereinbefore at least two solar cells or solar cell units can be arranged in mutually superposed relationship, in which case it is also possible to provide photovoltaic semiconductor layers which can absorb light from different light wavelength ranges.

It can however also be provided that the solar cell units are multifunction cells. Those cells have active regions which adsorb light from different light wavelength ranges so that an increase in efficiency is achieved thereby.

In that respect it can be provided that two mutually superposed solar cells or solar cell units are applied on both sides of the shrink film.

It is possible that the solar cells or solar cell units provided on the one side of the shrink film are applied in displaced relationship with respect to the solar cells or solar cell units on the other side of the shrink film. In that way for example the intermediate spaces between adjacent solar cells can be filled up by further solar cells arranged on the opposite side of the shrink film or the injection backing and thus the active area of the solar cell units can be further enlarged.

Further advantageous configurations are afforded by the fact of the solar cells being in the form of film bodies.

It can be provided that the solar cells and/or the solar cell units are shrunk on to mounting bodies. The mounting bodies can be for example bodies in plate form, which beside contact tracks for making electrical connections can have fixing elements.

It can also be provided that the solar cells or the solar cell units are of a tubular configuration, in which respect it can further be provided that the tubes are used as a conduit for a medium or the tubes if necessary are cut open at a generatrix thereof. The above-mentioned medium can involve water which is circulated by way of a pump driven by solar current. On the one hand the water is heated by the solar radiation and on the other hand it is also conveyed and the heat energy of the water is fed to a heat exchanger.

It can further be provided that the solar cell units are encapsulated.

It is provided that solar cells and/or solar cell units are assembled to constitute solar cell modules. The solar cell modules can form marketable units which can be connected to form photovoltaic installations. The above-mentioned encapsulation can extend to all the specified units or can be provided in succession a plurality of times.

The shapes in the surface of the solar cells which are afforded by the above-described process steps by virtue of the shrink film are usually in the form of raised portions or depressions of a height and depth respectively in the range of between 1 mm and 20 mm. They are preferably at a spacing of between 5 mm and 25 mm. These therefore involve shapes which are generally perceptible with the naked eye and which can therefore be referred to as macroscopic shapes. The raised portions or depressions however can also be smaller and can be down to 30 μm. Equally it is possible to provide much smaller spacings which are down to 30 μm.

It is further possible for the surface area of the organic semiconductor layer to be enlarged by the organic semiconductor layer and/or optionally further electrical functional layers of the solar cell being applied to a surface which already has a corresponding surface profile, for example an embossing film. This preferably involves a surface structure which is introduced into a replication lacquer layer or a plastic film by means of an embossing process or a UV replication process and which has a microscopic surface profile with a depth-to-width ratio of between 0.1 and a spacing between the raised portions of between 200 nm and 100 μm.

In a further advantageous configuration it is provided that the solar cell which is shaped after manufacture thereof is produced by means of one of the above-mentioned processes. The above-described solar cell with microscopic shapings is thus shaped after manufacture thereof, in such a way that at least the top side of the solar cell has a surface profile which enlarges the surface area of the top side in relation to a flat surface profile. There is therefore proposed a process which, in the solar cell, produces both a (macroscopic) surface profile which is generally also followed by the active layer of the solar cell, and also a (microscopic) surface profile at least in the active layer of the solar cell.

Further advantageous implementations of the invention are directed to the configuration of the surface profile of the solar cells or solar cell units produced by the above-described processes.

It can be provided, that the surface profile is such that it leads to multiple reflections and thus increases the efficiency of the solar cell. Apart from the special cases where a light beam impinges perpendicularly on the surface of the solar cell—the energy of the light beam is put to maximum use—or is directed parallel to the surface of the solar cell—the energy of the light beam is not used—a part of the light is reflected on being incident on the surface of the solar cell. Consequently a part of the light energy is lost if the reflected beam does not impinge on the surface of the solar cell again. When using a surface with a flat surface profile, a light beam incident on the surface is reflected only once. An uneven surface profile however can lead to multiple reflections. If for example the arrangement has a sawtooth-shaped surface profile with a crest angle of 90°, the light beam is reflected twice on average, apart from the fact that the available surface area is also enlarged in relation to a flat surface. It can further be provided that the surface profile is formed from raised portions and/or depressions of the carrier substrate and/or the semiconductor layer. In that respect it can also be provided that the carrier substrate is formed from a shaped film or plate, on which the polymer solar cell which is made up of thin layers is arranged. The semiconductor layer can be for example applied in a layer thickness of between 150 nm and 200 nm. Each of the two electrode layers can be of a thickness of between 10 nm and 50 nm, but it is also possible to use thicknesses in the range of between 50 and 1000 nm, depending on the conductivity required. It can further be provided that the semiconductor layer is also formed with raised portions and/or depressions. For example the carrier substrate can have macroscopic raised portions and/or depressions and the semiconductor layer microscopic raised portions and depressions.

Further implementations are directed to the configuration of the surface profile.

It can be provided that the surface profile is a stochastic surface profile. The stochastic surface profile can preferably be provided for microscopic surface profiles, that is to say preferably in the form of a surface profile on the semiconductor layer. Stochastic surface profiles which have structures below the resolution capability of a naked human eye are also known as matt structures. Electrode layers involving the above-mentioned thickness of between 10 and 50 nm can be applied to the semiconductor layer without ‘smearing’ the microscopic surface profile of the semiconductor layer. Thin layers can exactly follow the surface profile and form a surface corresponding to the surface profile. Thick layers form a surface which at least in partial regions thereof no longer follows the surface profile and therefore ‘smears’ it. However, a smeared surface profile can also be tolerated by matching the refractive indices of the layer or layers arranged over the top side of the semiconductor layer, for example an electrode layer. If the refractive index difference in the refractive indices of the semiconductor layer and the layer partially or completely filling up the surface profile is at least >0.2, but is not so great that total reflection occurs at the interface between the layer and the semiconductor layer, the increase in surface area of the semiconductor layer is optically effective independently of the configuration of the layer covering the surface profile.

It can further be provided that the surface profile is a periodic surface profile. The periodic surface profile can be provided both for macroscopic and also for microscopic structures. It is preferred in particular in relation to macroscopic surface structures or if there is a defined magnitude in respect of surface area enlargement, that is accessible to exact calculation. It can also be preferred to reduce the tool expenditure for transfer of the surface profile. A periodic profile is particularly suitable for a roll-to-roll production process in which the surface profile can be transferred from a rotating profile roller on to the semiconductor layer. A further advantage of the periodic profile is that only one period of the profile has to be designed and fashioned to optimise the properties of the periodic profile.

It can be further provided that the surface profile forms a cross grating comprising two base gratings. The surface profile can have for example a cross grating comprising two base gratings of periods of less than a limit wavelength λ at the short-wave end in the spectrum of visible light, that is to say between λ=380 nm and λ=420 nm and profile depths in the range of between h=50 nm and h=500 nm. Such relief structures absorb almost all visible light incident on the surface and provide for backscattering of only a small fraction of the incident light. The percentage of the absorbed light depends non-linearly on the profile depth and can be controlled by means of the choice of the structure depth of between 50% and about 99%, in which respect, the flatter the surface profile, the correspondingly more incident light is backscattered and correspondingly less light is absorbed. As tests have shown, a depth-to-width ratio in the range of between 0.5 and 5 has proven to be particularly advantageous, as described in greater detail hereinafter. In a further configuration it is provided that the surface profile is a self-similar surface profile. The portions of self-similar profiles are similar to the profile itself. In that way a surface profile can be further divided up without losing the character of the surface profile. Thus for example the branches of a tree are similar to the tree itself. In mathematics self-similar functions are also referred to as fractals.

It can be provided for example that a sinusoidal surface profile is superposed with a sine function which in turn can be superposed with a sine function, and so forth. If for example the raised portions and/or the depressions involve a height profile h=±100 μm, its raised portions can have and/or a height profile h′=±10 μm which in turn can be modulated with a height profile h″=±1 μm. Further profiling now produces structure elements of the order of magnitude of visible light which includes wavelengths of 760 nm (red) to 380 nm (violet). Optical-diffraction effects at such small structures could however have the result that the efficiency of the solar cell decreases again.

It can be provided that the mean width or the mean diameter of the raised portions or depressions at the base point is in the range of between 1 mm and 10 mm.

It can further be provided that the mean width or the mean diameter of the raised portions and/or depressions at the base point is in the range of between 1 μm and 1000 μm. Under ideal conditions the resolution capability of the naked human eye is about 1′, that is to say 1 mm at 3.5 mm or about 70 μm at 250 mm. Therefore the limit between macroscopic and microscopic structures extends in the range of between 1 μm and 1000 μm.

It can be still further provided that the mean width or the mean diameter of the raised portions and/or depressions at the base point is in the range of between 100 nm and 1000 nm. In the case of surface structures in the nanometer region, as stated hereinbefore, it is to be observed that the surface structures can be smeared by the layer adjacent thereto.

It can further be provided that the depth-to-width ratio of the raised portions and/or depressions is in the range of between 0.5 and 5. The depth-to-width ratio which is also referred to as the aspect ratio affords as a dimension-less number information as to the ratio in which the depths of the ‘troughs’ and the height of the ‘peaks’ of the surface structure are related to the spacing of two adjacent structure elements. With an increasing depth-to-width ratio the surface area of the surface structure is enlarged. Practical limits are set inter alia by virtue of the fact that the flanks of the raised portions and/or depressions become steeper with an increasing depth-to-width ratio, whereby those increasingly shallower angles are encountered by the incident light beams (in the event of perpendicular incidence on the surface) or are at least partially no longer encountered at all (in the event of inclined incidence on the surface).

On the one hand, with an increase in the steepness of the flanks, there is an increase in the probability of multiple reflections which, as described hereinbefore, increase the efficiency of the solar cell. On the other hand steep flanks can have a shadowing effect, in particular for beams which are incident at a shallow angle relative to the surface. A depth-to-width ratio for the structure elements of between 0.5 and 5, preferably between 1 and 5, has proven to be of significance for the occurrence of multiple reflections which significantly increase the efficiency of the solar cell. The shape of the flanks can also influence the number of reflections. A flat flank, for example a flank of a sawtooth profile, acts as a flat mirror while a curved flank can focus or disperse the beams, for example a concave flank can focus them. The base gratings referred to hereinbefore, forming a cross-grating, can extend for example in accordance with a sine square function, but rectangular or pyramid structures are also possible. In that case surface structures which are like an egg box are formed. Such structures also lead to a further increase in the efficiency of the solar cell.

Further implementations are directed to the geometrical configuration of the raised portions and/or depressions.

It can be provided that the peripheral surfaces of the raised portions and/or the depressions are in the form of surface regions of a spherical body.

It can further be provided that the spherical body is a ball.

It can also be provided that the peripheral surfaces of the raised portions and/or the depressions are in the form of surface regions of a cone or a pyramid.

The surface area enlargement which can be attained will now be calculated by way of example on a pyramid-like raised portion with a square base surface which has a base edge length a and a height h=2.96 a, that is to say a depth-to-width ratio of 2.96.

The surface area of the base surface O₀ is:

O₀=a·a=a²

The surface area of the surface of the pyramid A₁ is:

O₁=4·a/2·(a²/4+h²)^{1/2}=2a·(a²/4+8.76a²)^{1/2}≈6a²

Accordingly the surface area enlargement O₁/O₀ is:

O₁/O₆=6.

The surface area of the polymer solar cell, increased by the factor of 6, can be still further increased by use of the above-described process for producing the surfaces of raised portions and/or depressions with further raised portions and/or depressions, for example with three steps, by the factor of 216. Even on the assumption that not all surface portions are optimally oriented in relation to the light source, the polymer solar cell according to the invention has a markedly enlarged active surface area in relation to a polymer solar cell having a flat surface, with multiple reflections that this entails and which lead to an increase in efficiency.

In a further advantageous configuration it can be provided that the raised portions and/or the depressions are of star-shaped cross-section. In that respect the expression star-shaped cross-section is used to denote all cross-sectional shapes which have extensions starting from a common starting point.

It can further be provided that the peripheral surfaces of the raised portions and/or the depressions are in the form of peripheral surfaces of a recumbent prism or cylinder. Such raised portions and/or depressions, extending in one direction, can have preferred orientations in respect of which the efficiency of the solar cell is at its greatest. It can however also be provided that the orientation of the raised portions and/or depressions is altered region-wise, for example in each case through 90°, to reduce or cancel the directional dependency.

Particularly for producing microscopic surface profiles the raised portions can be transferred for example by intaglio printing on to the surface of the semiconductor layer or layers or the surface of the carrier substrate. If there is provided a carrier substrate which has a shaping action for forming the semiconductor layer, the raised portions can be formed for example from a radiation-hardening lacquer, for example a UV-hardening lacquer. It is however also possible to use other lacquers or printing inks. In that respect, this can also involve reflecting lacquer so that incident light is deflected both on to the front side and also on to the rear side of the polymer solar cell.

If the raised portions and/or depressions are produced on the semiconductor layer, a semiconductor layer of a constant layer thickness can firstly be applied to the (flat) carrier layer and then the raised portions and/or depressions can be applied by means of intaglio printing. For that purpose it can be provided for example that the regions of the intaglio printing form which produce the raised portions are filled with semiconductor material and the regions which produce the depressions represent unengraved regions on the intaglio printing roller. Organic semiconductors can involve a consistency which is then suitable for such a printing procedure. In that case it is necessary to directly freeze in the printing points.

It can further be provided that the heightwise profile is formed from depressions and/or raised portions introduced into the carrier layer. The depressions can be introduced into the carrier layer which can be in the form of a replication layer by thermal embossing, in which case the depressions can be of such a dimension that the raised portions are shaped at the same time. It can further be provided that the carrier layer is formed from a radiation-hardening lacquer, such as for example the above-mentioned UV lacquer, and the surface profile is shaped into the radiation-hardening lacquer optically or by means of a profile roller, and the lacquer is then hardened. It is however also possible to entail macroscopic depressions and/or raised portions, as can be found for example in packaging films.

In a further advantageous configuration it is provided that the surface profile is formed by an additive superpositioning of a macroscopic surface profile with a microscopic surface profile.

The above-described embodiments are not limited to polymer solar cells but can also be transferred on to organic solar cells in which the semiconductor layer is not formed from a polymer but from non-crosslinked organic molecules, as well as inorganic solar cells, at least as regards the semiconductor layer, and hybrid solar cells which are made from organic and inorganic components.

Furthermore the solar cells can involve both single junction cells, that is to say cells with a photosensitive layer, and also multijunction cells, that is to say cells having a plurality of photosensitive layers. The photosensitive layers of the multijunction cell can be sensitised for different wavelength ranges so that it is possible to use a comparatively larger wavelength spectrum than with the single junction cell.

The invention is described by way of example hereinafter by means of a number of embodiments with reference to the accompanying drawings in which:

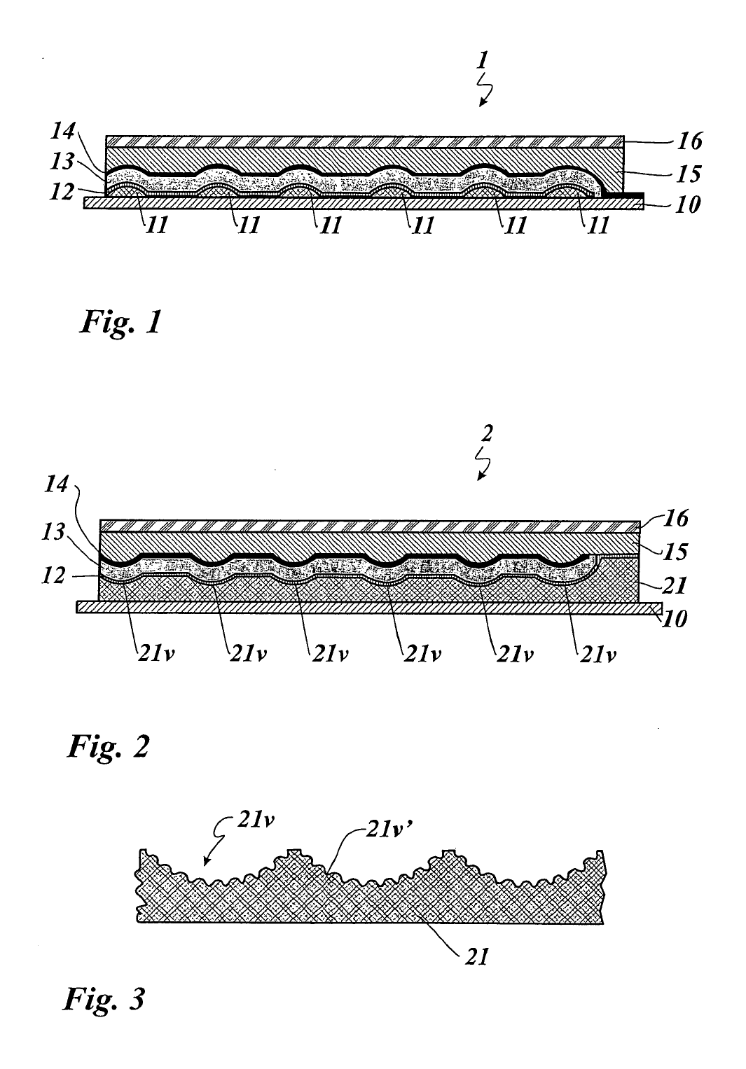

FIG. 1 shows a first embodiment of a polymer-based solar cell according to the invention,

FIG. 2 shows a second embodiment of a polymer-based solar cell according to the invention,

FIG. 3 shows a detail view on an enlarged scale from FIG. 2,

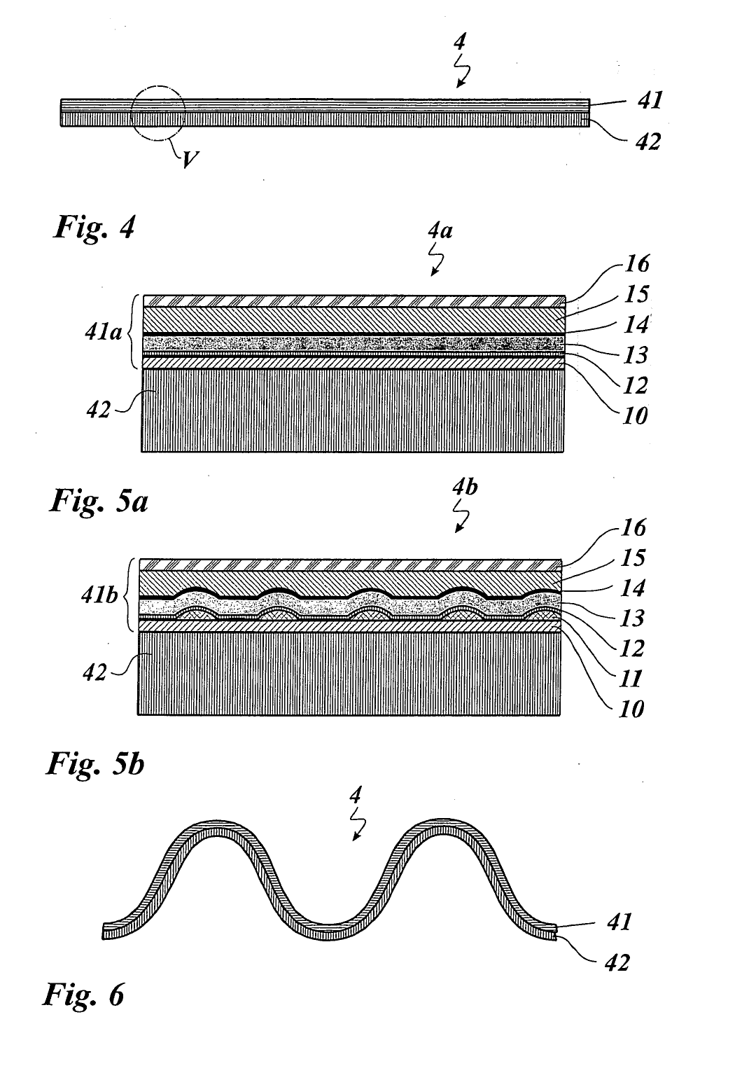

FIG. 4 shows a diagrammatic view in section of a first embodiment of a solar cell unit according to the invention prior to a temperature treatment,

FIG. 5a shows a detail view V from FIG. 4 with a first solar cell configuration,

FIG. 5b shows a detail view V from FIG. 4 with a second solar cell configuration,

FIG. 6 shows a diagrammatic view in section of the solar cell unit of FIG. 4 after the temperature treatment,

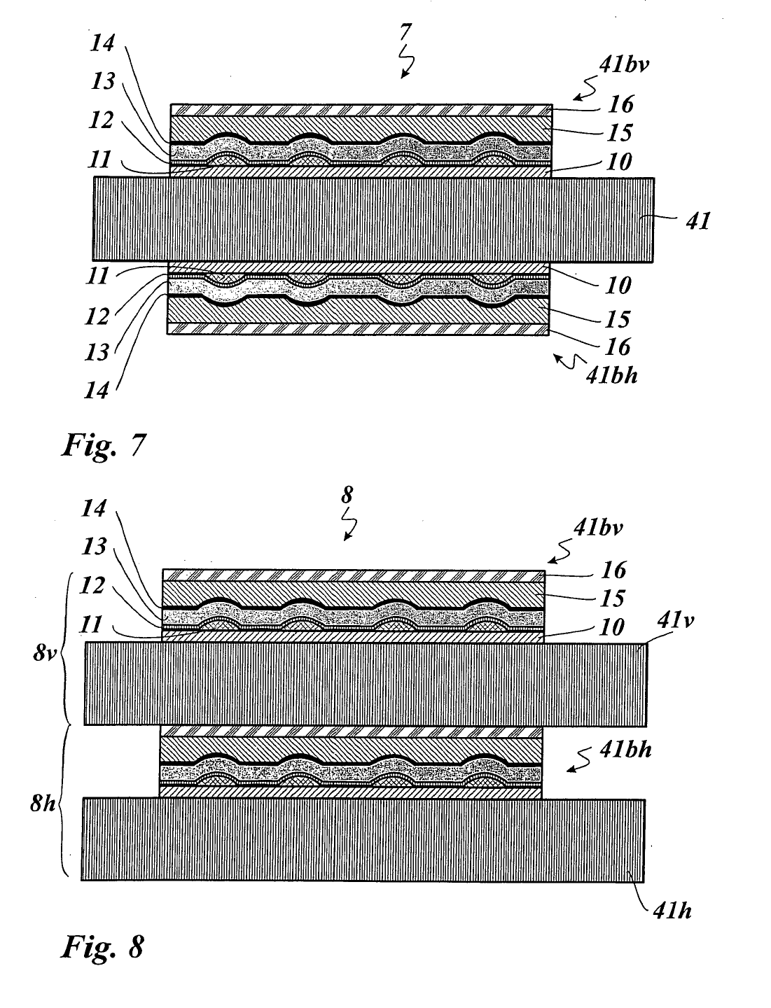

FIG. 7 shows a diagrammatic view in section of a second embodiment of a solar cell unit according to the invention,

FIG. 8 shows a diagrammatic view in section of a third embodiment of a solar cell unit according to the invention,

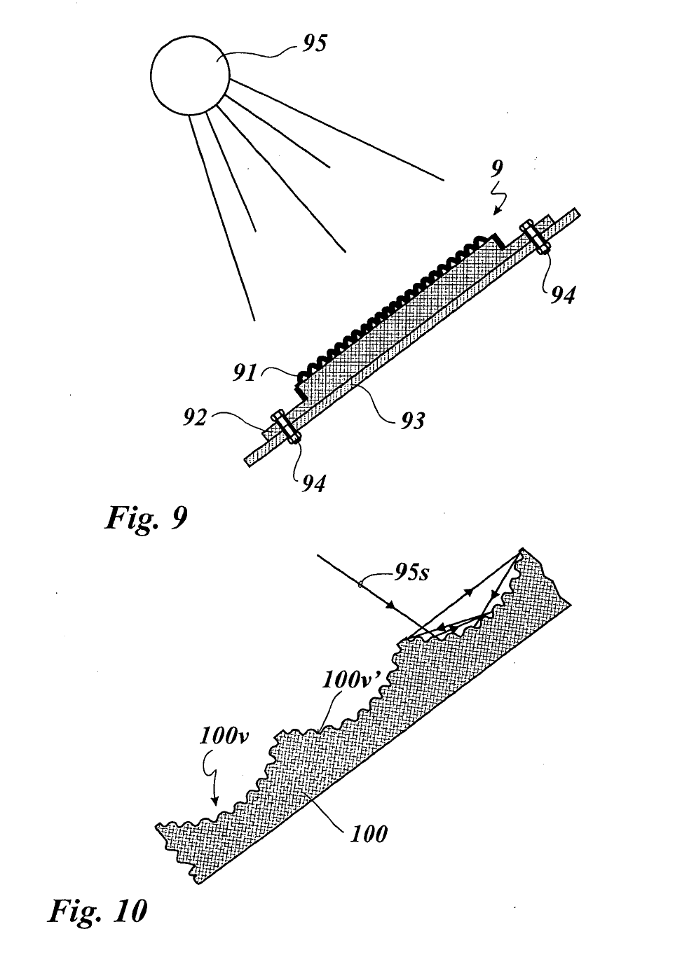

FIG. 9 shows a diagrammatic view in section of an example of use of the solar cell unit in FIG. 4, and

FIG. 10 shows a diagrammatic view relating to the occurrence of multiple reflections at a surface according to the invention.

FIG. 1 shows a polymer-based solar cell 1, hereinafter referred to as a polymer solar cell, which is constructed on a carrier substrate 10. The carrier substrate 10 can involve for example a polyester film of between about 20 and 125 μm in thickness.

Arranged on the carrier substrate 10 are form elements 11 which as in the illustrated embodiment can be arranged distributed uniformly on the carrier substrate 10 or which can be distributed as desired. In the FIG. 1 embodiment the form elements 11 are in the form of segments of a ball and are of a height h of for example 6 μm and a diameter 2ρ of for example 50 μm. They are applied by printing to the carrier substrate 11, prior to the application of the first electrode layer 12. The effective surface area which is available for construction of the polymer solar cell 1 is increased in relation to the flat surface of the carrier substrate 10 by means of the form elements 11.

The surface area of a segment of a ball is:

O₁=2π·r·h=π·(ρ²+h²)

On the assumption of dense ball packing each ball dome requires a base surface:

O₀=πρ²

Accordingly the maximum enlargement in surface area with the above-specified values by way of example is:

O₁/O₀=1+h²/ρ²=1+36/625=1.05

In that way the surface area of the polymer solar cell 1 is enlarged, with the same base surface for the polymer solar cell 1. Because the ball has the smallest surface area of all geometrical bodies, the foregoing calculation at the same time gives the smallest possible increase in surface area. The increase in surface area depends very greatly on the parameters selected for ρ and h. If for example with ρ=25 μm, the value h is raised from 6 mm to 15 mm, the surface area ratio changes from 1.05 to 1.28.

On the assumption that the ball segments are hemispheres, that gives:

O₁/O₀=(2πr²+4r²−πr²)/4r²=π/4+1=1.79

If in contrast the raised portions are formed from four-sided pyramids, the height of which is equal to the base side, the increase in surface area is:

O₁/O₀=(4/2·a·(a²/4+a²)^{1/2})/a²=2.236

It is advantageous in that context that, in the choice of four-sided pyramids, the total surface area can be so structured that no intermediate spaces remain. While ball domes can have a maximum depth-to-width ratio of 1, in all other geometrical shapes of the raised portions or depressions respectively such as pyramids, cones, prisms or the like, the depth-to-width ratio is not limited by the geometrical shape. It will be noted however that ball domes are particularly simple to manufacture so that the disadvantage of having the smallest specific area of all configurations can be compensated thereby. It can also be provided that the form elements are in the form of recumbent strip-shaped prisms, that is to say it is possible for the surface of the solar cell to be in the form of a corrugated sheet.

The form elements 11 can be applied for example by printing, preferably with an intaglio printing process, or they can be replicated, as described hereinafter with reference to FIG. 2. The form elements 11 can be transparent or non-transparent, depending on the structure of the solar cell and the light guidance effect.

In regard to the structural configuration of the form elements 11 it is to be noted that the effectiveness of a solar cell depends inter alia on the angle of inclination at which the radiation is incident and is guided into the solar cell. Surface portions oriented in parallel relationship to the direction of the radiation therefore contribute nothing to the generation of energy from the incident radiation and do not increase the efficiency of the polymer solar cell.

In addition the increase in surface area which can be achieved depends on the number of elements 11 per unit of surface area.

Applied to the form elements 11 and to the portions of the carrier substrate 10, that are not covered by the elements 11, is a first electrode layer 12 which for example can be a layer of gold, silver, copper, aluminum or an alloy of those and/or further metals. The first electrode layer 12 can however also be formed for example from a conducting ITO coating (indium/tin oxide). The first electrode layer 12 is in the form of a transparent electrode layer a few nanometers in thickness. This can also be a semitransparent electrode layer which for example can be in the form of a metallic layer, a structured metallic layer or an optically closed layer.

Arranged on the first electrode layer 12 is a photosensitive semiconductor layer system 13 which can comprise for example a PEDOT/PSS layer, a photoelectric semiconductor layer and a TiO₂ layer. Other electrode layers and/or hole blocker layers are also conceivable.

Arranged on the photosensitive semiconductor layer system 13 is a second electrode layer 14 which can be formed like the above-described first electrode layer 12.

The second electrode layer 14 is covered over by an adhesive layer 15 to which a cover layer 16 is applied. It is also possible to dispense with the adhesive layer. The cover layer can be a transparent plastic layer or a barrier layer structure which protects the system from external influences.

The operating principle of the polymer solar cell is based on light-induced electron transfer in what is referred to as a donor-acceptor system. The above-described increase in the surface area of the polymer solar cell can at least partially eliminate the disadvantage of the lower efficiency of a polymer solar cell and positively influence it, which is also based on the multiple reflection caused by the enlarged surface area.

FIG. 2 now shows a second embodiment of the polymer solar cell according to the invention in which the enlargement in the surface area is achieved not by raised portions as shown in FIG. 1 but by depressions.

A polymer solar cell 2 has a replication layer 21 which is applied to the carrier substrate 10 and which is formed with depressions 21v on its front side that is towards the first electrode layer 12. The depressions 21v can involve many different forms similarly to the above-described form elements 11. The replication layer 21 can be a layer or layers which is or are applied to a carrier substrate and in which the depressions 21v are shaped by a heated shaping tool which is brought into contact under pressure with the surface of the replication layer 21. It can also be provided in that respect that the replication layer is made from a radiation-hardening lacquer, for example a UV-hardening lacquer, which is hardened by irradiation with UV light after the depressions 21v have been shaped.

In the embodiment shown in FIG. 2 it is possible to dispense with the replication layers on the carrier substrate 10. In that case the carrier substrate represents the replication layer 21 in which the structures (depressions) are directly shaped. Alternatively the depressions can be shaped in the carrier substrate.

The second electrode layer 14 which is applied as an upper electrode to the photosensitive semiconductor layer system 13 is covered, as in the above-described first embodiment (FIG. 1), by the adhesive layer 15 to which the cover layer 16 or also a plurality of layers is or are applied.

FIG. 3 now shows a portion on an enlarged scale of the replication layer 21. The surface of the depressions 21v has a relief structure similar to the macrostructure shaped in the surface of the replication layer 21. The surface of the depressions 21v therefore has depressions 21v′ similar to the depressions 21v. The depressions 21v′ can in turn have depressions similar to the depressions 21v′, and so forth. It can therefore be provided for example that the depressions 21v are of a depth of 100 μm, the depressions 21v′ are of a depth of 10 μm and the following depressions are respectively of a depth which is 10% of the preceding depth. The lower limit can be reached for example when diffraction occurs at the surface structures and light can no longer penetrate into the semiconductor layer 13.

The surface structuring increases the effective surface area of the depressions in relation to the effective surface area of smooth depressions or raised portions respectively (see FIGS. 1 and 2). Such a surface structure can be in the form of a self-similar structure or a fractal structure. An example of a fractal structure is what is referred to as the Koch curve which is characterised by its triangular protuberances. That surface structure can result in multiple reflections and thus an increase in the efficiency of the cell.

FIG. 4 now shows a solar cell unit 4 formed from a solar cell 41 and a shrink film 42. The shrink film 42 can preferably be a PE shrink film of a thickness of between 20 μm and 75 μm. Other thicknesses are also possible.

After its manufacture the solar cell 41 is laminated on to the shrink film 42, in which case it can be provided that a plurality of solar cells are laminated on to the shrink film, which solar cells can be connected in parallel and/or in series for example by conductor tracks. The conductor tracks can be produced on the shrink film 42 in a conductor track layer not shown in FIG. 4. The conductor track layer can involve a structured metal layer, formed for example from gold, silver or copper.

FIG. 5a now shows a view on an enlarged scale of the layer-wise structure of a solar cell unit 4a in which a polymer-based solar cell 41a is applied to the shrink film 42. The solar cell 41a is in principle constructed like the solar cell 1 in FIG. 1, but it does not have any form elements 11. It is therefore constructed with a flat active layer without a surface profile.

The carrier substrate 10 can be for example a polyester film of between about 20 and 50 μm in thickness.

The first electrode layer 12, the photosensitive semiconductor layer system 13, the second electrode layer 14, the adhesive layer 15 and the cover layer 16 are applied in succession on the side of the carrier substrate 10 remote from the shrink film 42. The layer structure is described in detail hereinbefore with reference to FIG. 1.

FIG. 5b now shows a view on an enlarged scale of the layer-wise structure of a solar cell unit 4b in which a polymer-based solar cell 41b is applied to the shrink film 42. The solar cell 41b is constructed like the solar cell 1 in FIG. 1.

The carrier substrate 10 can be for example a polyester film of between about 20 and 50 μm in thickness.

Arranged on the side of the carrier substrate 10 remote from the shrink film 42, as described hereinbefore with reference to FIG. 1, are the form elements 11 which are applied by printing to the carrier substrate 10 prior to the application of the first electrode layer 12. The photosensitive semiconductor layer system 13, the second electrode layer 14, the adhesive layer 15 and the cover layer 16 are applied to the first electrode layer 12.

FIG. 6 now shows the solar cell unit 4 in FIG. 4 after a temperature treatment of about 3 minutes at a temperature of between 80° C. and 120° C. The temperature range is so selected that it is not reached in operational use of the solar cell unit and that it does not destroy the structure of the solar cell 41. In the embodiment shown in FIGS. 4 and 5 the shrink film 42 is a unidirectional shrink film which shrinks only in one direction under the effect of temperature.

As can be seen from FIG. 6 the solar cell unit 4 is now sinusoidally shaped in cross-section so that the surface area of the top side of the solar cell unit 4 is enlarged in relation to a flat surface profile. Accordingly solar radiation directed on to the solar cell is reflected a plurality of times by virtue of the curved larger area of the active layer, which is not the case with the undeformed solar cell unit 4 in FIG. 4.

If the solar cell 41 is of the type of the solar cell 41a shown in FIG. 5a, in which the active layer has a flat surface profile, the above-mentioned surface area enlargement of the solar cell unit 4a results only from the deformation of the solar cell 41a due to the temperature-treated shrink film 42. If in contrast the solar cell 41 is of the type of the solar cell 41b shown in FIG. 5a, in which the active layer has an uneven surface profile, the above-mentioned surface area enlargement of the active layer of the solar cell unit 4b results both from the deformation of the solar cell 41b by the temperature-treated shrink film 42 and also from the surface area enlargement of the photosensitive semiconductor layer system 13 as a consequence of the form elements 11. Therefore the surface profile produced in that way involves a superpositioning of a first (macroscopic) surface profile with a second (microscopic) surface profile, thereby achieving a further increase in efficiency of the solar cell unit by multiple reflections. The macroscopic surface profile can further be so designed that it preferably deflects incident light on to the active layer of the solar cell 41. It can further be provided that the shrink film is provided with lacquer and/or a coating material, to which there are added light-refracting and/or light-scattering and/or light-conducting and/or light wavelength-changing particles and/or particle mixtures. If the shrink film is in the form of a transparent film the light can also be applied to the solar cell through the shrink film and in that case influenced by the above-mentioned particles and/or particle mixtures.

Instead of the solar cell shown in FIG. 5b, in which the surface profile is formed by form elements 11, as stated in FIG. 1, it is also possible to provide a solar cell in which the surface profile is shaped in the replication layer 21, as shown in FIG. 2.

The solar cell unit 4 shown in FIG. 6 can also be shaped by an inmold process or a touch forming process. In that case the solar cell 41 is placed in an evacuatable mold and heated and then pressed by the application of a vacuum against a film provided with a surface structure. In that case the surface structure of that film is formed in the surface of the solar cell 41 or the solar cell 41 is overall shaped. For fixing the shaping the shaped solar cell 41 has thermoplastic material injected therebehind, that material performing the function of the shrink film 42.

Deep drawing can be used as a further production process, in which case a thermoplastic film can be provided instead of the shrink film 42. The solar cell 41 and the thermoplastic film form a deep drawing film which is placed in a deep drawing mold and heated and then pressed by means of pressure into the deep drawing mold and in that case shaped. The deep drawing mold is in the form of a negative of the surface profile which is to be shaped in the deep drawing mold. It can be provided that the deep drawing mold is backed by injection molding after shaping thereof to stabilise it to prevent subsequent deformation.

FIG. 7 now shows a solar cell unit 7 in which two solar cells 41b (see FIG. 5b) are laminated on to the shrink film 41 on both sides thereof. In the FIG. 7 embodiment, a front solar cell 41bv and a rear solar cell 41bh are arranged in mutually opposite relationship, the respective carrier substrates 10 of the solar cells being joined to the shrink film 41. In this embodiment the shrink film 41 is in the form of a transparent film so that incident light firstly impinges on the photosensitive semiconductor layer system 13 of the front solar cell 41bv, then passes through the transparent shrink film 41 and finally impinges on the photosensitive semiconductor layer system 13 of the rear solar cell 41bh. In that way the solar cell unit 7 can more effectively use solar energy. It can also be provided that the front solar cells 41bv and the rear solar cells 41bh are arranged in mutually displaced relationship so that for example the rear solar cells 41bh are arranged in alignment in relation to the regions provided for contacting on the front side of the shrink film 41, which do not contribute to energy generation. It is also possible that the photosensitive layers are of different configurations and absorb light from different wavelength ranges. Such cells are also referred to as multijunction cells, in contrast to the single junction cells which have only one photosensitive layer. A multijunction cell can use a greater spectral range than a single junction cell and therefore has a comparatively higher level of energy conversion efficiency than a single junction cell.

FIG. 8 shows a solar cell unit 8 formed from a front solar cell unit 8v which is towards the light source and a rear solar cell unit 8h arranged therebehind. The two solar cells units 8v and 8h form a common multilayer body, in which respect it can be provided that their shrink films 41v and 41h are made from the same material and/or have the same shrink characteristics. It can however also be provided that the shrink films 41v and 41h are made from different materials and/or have different shrink characteristics. Further variants can be produced by varying the orientation of the interconnected solar cell units 8v and 8h. It can therefore be provided for example that the shrink films 41v and 41h are unidirectional shrink films which are arranged crossed through 90° so that, after the temperature treatment, the solar cell unit 8 has a knob-shaped surface profile. It can also be provided here that the various solar cell units are formed in the same fashion or differently from single junction cells and/or multijunction cells.

The solar cell units 7 and 8 shown in FIGS. 7 and 8 are in the condition which they have prior to the temperature treatment, that is to say the shrink films 41, 41v and 41h are not yet deformed.

It can preferably be provided in the embodiments described with reference to FIGS. 4 through 8 that the solar cell units are provided with protective coatings and/or they are shrunk on to mounting bodies. Such an example of use is shown in FIG. 9.

FIG. 9 shows a solar cell module 9 which is arranged by means of fixing elements 94 on a mounting surface 93 and which is towards a light source 95. The mounting surface 93 can be a roof surface of a building, preferably a roof surface on the south side of the building.

The solar cell module 9 has a solar cell unit 91 shrunk on to the front side of a mounting body 92. The mounting body 92 is in the form of a plate-shaped body having a projecting mounting portion embraced by the solar cell unit 91 which is shrunk thereon. The edge portions of the mounting body 92, in the FIG. 9 embodiment, have through holes through which extend fixing elements 94 in the form of cheese-head screws.

As described hereinbefore the solar cell unit 91 has one or more shrink films. The surface profile of the solar cell unit 91, after the shrink operation, enlarges the surface area of the top side of the solar cell unit 91 in relation to a flat surface profile. In the shrink operation, further electrical connections can be made with electrical contacts and/or conductor tracks of the mounting body 92. The electrical connections can be protected at the same time from corrosion and weathering influences by the hood-form configuration of the shrunk solar cell unit 91.

It can further be provided that the solar cell unit comprises hoses, through which water flows, with a solar cell shrunk thereon. In that case the thermal radiation of the sun can also be additionally used. FIG. 10 now shows a diagrammatic view illustrating the occurrence of multiple reflections at a surface according to the invention of a solar cell 100. The surface of the solar cell 100 has depressions 100v in which depressions 100v′ are shaped. A light beam 95s impinging on the surface of the solar cell 100 is reflected a plurality of times at the surface of the solar cell, giving off a part of its energy to the solar cell at each reflection. In the FIG. 10 embodiment the light beam 95s is reflected five times. On the simplifying assumption that, at each reflection, 50% of the energy is transferred into the solar cell 100, the energy balance sheet is as follows:

| Reflection | Energy transfer |
|---|---|
| 1st reflection | 50% |
| 2nd reflection | 25% |
| 3rd reflection | 12.5% |
| 4th reflection | 6.25% |
| 5th reflection | 3.13% |
| | 96.66% |

Although the five reflections referred to in the example do not occur for every incident light beam (different impingement point, different direction of incidence), nonetheless two reflections for example already provide an energy transfer of 75%.

Structures with a depth-to-width ratio in the range of between 0.5 and 5 have proven to be particularly advantageous for producing multiple reflections.

As has further been shown, in particular cross gratings comprising two base gratings involving the above-specified depth-to-width ratio are suitable as the surface structure. The structures may involve for example a sine-square configuration but rectangular or pyramidal structures are also suitable. They are thus similar to an egg box.

1-46. (canceled)

47. A process for the production of a solar cell unit comprising a polymer-based solar cell having at least one carrier substrate and at least one organic semiconductor layer having a top side towards a light source and a rear side away from the light source, wherein
the solar cell after production thereof is so shaped that at least the top side of the solar cell has a surface profile which enlarges the surface area of the top side in relation to a flat surface profile, and the top side of the organic semiconductor layer has a surface profile which is formed by an additive superpositioning of a macroscopic surface profile with a microscopic surface profile.

48. A process as set forth in claim 47, wherein the solar cell is laminated on to a shrink film and thereafter the solar cell unit is subjected to a temperature treatment.

49. A process as set forth in claim 47, wherein a shrink film is used for the carrier substrate of the solar cell and after its manufacture the solar cell is subjected to a temperature treatment.

50. A process as set forth in claim 48, wherein a unidirectional shrink film is used.

51. A process as set forth in claim 48, wherein a bidirectional shrink film is used.

52. A process as set forth in claim 48, wherein an opaque or transparent or semi-transparent shrink film is used.

53. A process as set forth in claim 48, wherein an electrically non-conducting shrink film is used.

54. A process as set forth in claim 48, wherein an electrically conducting shrink film is used.

55. A process as set forth in claim 48, wherein the shrink film is at least region-wise lacquered and/or coated prior to the temperature treatment.

56. A process as set forth in claim 55, wherein light-diffracting and/or light-scattering and/or light-conducting and/or light wavelength-changing particles and/or particle mixtures are added to the lacquer and/or the coating material.

57. A process as set forth in claim 48, wherein the shrink film is at least region-wise prestructured.

58. A process as set forth in claim 48, wherein a multi-layer shrink film is used, the layers of which involve different shrink characteristics.

59. A process as set forth in claim 48, wherein two mutually superposed solar cells or solar cell units are mounted on both sides of the shrink film.

60. A process as set forth in claim 59, wherein the solar cells or solar cells units provided on the one side of the shrink film are applied in displaced relationship with respect to the solar cells or solar cell units provided on the other side of the shrink film.

61. A process as set forth in claim 47, wherein the solar cell is shaped by an inmold process.

62. A process as set forth in claim 47, wherein the solar cell is shaped by a touch forming process.

63. A process as set forth in claim 47, wherein the solar cell is shaped by a deep drawing process.

64. A process as set forth in claim 47, wherein the shaping of the solar cell is influenced by means of one or more spacer layers.

65. A process as set forth in claim 47, wherein the solar cell is injection-backed.

66. A process as set forth in claim 65, wherein an electrically conductive injection medium is used.

67. A process as set forth in claim 66, wherein a partially electrically conductive injection medium is used.

68. A process as set forth in claim 65, wherein an electrically non-conductive injection medium is used.

69. A process as set forth in claim 65, wherein an opaque or transparent or semi-transparent injection medium is used.

70. A process as set forth in claim 47, wherein at least two solar cells or solar cell units are arranged in mutually superposed relationship.

71. A process as set forth in claim 47, wherein the solar cell units are encapsulated.

72. A process for the production of a polymer-based solar cell having at least one carrier substrate and an organic semiconductor layer with a top side towards a light source and a rear side remote from the light source, wherein
a surface relief is shaped into a layer of the solar cell and one or more electrical functional layers including the organic semiconductor layer is applied to the shaped surface relief so that the top side of the organic semiconductor layer has a surface profile which enlarges the surface area of the organic semiconductor layer in relation to a flat surface profile, and the surface profile is formed by an additive superpositioning of a macroscopic surface profile with a microscopic surface profile.

73. A process as set forth in claim 72, wherein the surface profile is shaped into the carrier substrate or into a replication lacquer layer applied to the carrier substrate.

74. A process for the production of a solar cell unit having a solar cell as set forth in claim 47, wherein the solar cell which is shaped after manufacture thereof is produced by means of a process wherein
a surface relief is shaped into a layer of the solar cell and one or more electrical functional layers including the organic semiconductor layer is applied to the shaped surface relief so that the top side of the organic semiconductor layer has a surface profile which enlarges the surface area of the organic semiconductor layer in relation to a flat surface profile, and the surface profile is formed by an additive superpositioning of a macroscopic surface profile with a microscopic surface profile.

75. A polymer-based solar cell having at least one carrier substrate and at least one organic semiconductor layer with a top side towards a light source and a rear side remote from the light source, wherein
at least the top side of the organic semiconductor layer has a surface profile which enlarges the surface area of the top side in relation to a flat surface profile, and the surface profile is formed by an additive superpositioning of a macroscopic surface profile with a microscopic surface profile.

76. A solar cell as set forth in claim 75, wherein the surface profile is so adapted that it leads to multiple reflections.

77. A solar cell as set forth in claim 75, wherein the surface profile is formed from raised portions and/or depressions of the carrier substrate and/or the semiconductor layer.

78. A solar cell as set forth in claim 75, wherein the surface profile is a stochastic surface profile.

79. A solar cell as set forth in claim 75, wherein the surface profile is a periodic surface profile.

80. A solar cell as set forth in claim 79, wherein the surface profile forms a cross grating comprising two base gratings.

81. A solar cell as set forth in claim 75, wherein the surface profile is a self-similar surface profile.

82. A solar cell as set forth in claim 77, wherein the mean width or the mean diameter of the raised portions or depressions at the base point is in the range of between 1 mm and 10 mm.

83. A solar cell as set forth in claim 77, wherein the mean width or the mean diameter of the raised portions or depressions at the base point is in the range of between 1 μm and 1000 μm.

84. A solar cell as set forth in claim 83, wherein the mean width or the mean diameter of the raised portions or depressions at the base point is in the range of between 100 nm and 1000 nm.

85. A solar cell as set forth in claim 77, wherein the depth-to-width ratio of the raised portions and/or depressions is in the range of between 0.5 and 5.

86. A solar cell as set forth in claim 77, wherein the peripheral surfaces of the raised portions and/or the depressions are in the form of surface regions of a spherical body.

87. A solar cell as set forth in claim 86, wherein the spherical body is a ball.

88. A solar cell as set forth in claim 77, wherein the peripheral surfaces of the raised portions and/or the depressions are in the form of surface regions of a cone.

89. A solar cell as set forth in claim 77, wherein the peripheral surfaces of the raised portions and/or the depressions are in the form of surface regions of a pyramid.

90. A solar cell as set forth in claim 77, wherein the raised portions and/or the depressions are of a star-shaped cross-section.

91. A solar cell as set forth in claim 77, wherein the peripheral surfaces of the raised portions and/or the depressions are in the form of peripheral surfaces of a recumbent prism or cylinder.
